(19) United States
(12) Patent Application Publication
(10) Pub. No.: US 2022/0223382 A1
(43) Pub. Date: Jul. 14, 2022

(54) SUBSTRATE PROCESSING APPARATUS AND CLEANING METHOD

(71) Applicant: Tokyo Electron Limited, Tokyo (JP)

(72) Inventor: Wataru SHIMIZU, Miyagi (JP)

(73) Assignee: Tokyo Electron Limited, Tokyo (JP)

(21) Appl. No.: 17/573,681

(22) Filed: Jan. 12, 2022

(30) Foreign Application Priority Data
Jan. 12, 2021 (JP) 2021-002526

(51) Int. Cl. H01J 37/32

(52) U.S. Cl. CPC H01J 37/32449; H01J 37/32834; H01J 2237/332; H01J 37/32633; H01J 2237/334; H01J 37/32862

(57) ABSTRACT

In a chamber, a stage that places a substrate that is provided as a target for substrate processing is provided in an inside thereof, and an exhaust port that discharges a gas in an inside thereof is formed at a position that is lower than that of the stage around the stage. A baffle plate is provided around the stage and divides an inside of the chamber into a processing space where substrate processing is executed for the substrate and an exhaust space that includes the exhaust port. An ejection port is arranged so as to eject a gas to the exhaust space. A gas supply unit supplies a cleaning gas that reacts with a product that is produced in the exhaust space to the ejection port.

### CROSS-REFERENCE TO RELATED APPLICATION

The present application claims priority to and incorporates by reference the entire contents of Japanese Patent Application No. 2021-002526 filed in Japan on Jan. 12, 2021, the entire contents of which are incorporated herein by reference.

### FIELD

The present disclosure relates to a substrate processing apparatus and a cleaning method.

### BACKGROUND

United States Patent Application Publication No. 2019/0218663 discloses an approach to form a film on a surface of a component and remove the film so as to execute cleaning thereof.

The present disclosure provides a technique that removes a deposition substance in an exhaust space efficiently.

### SUMMARY

According to an aspect of a present disclosure, a substrate processing apparatus includes: a chamber where a stage that places a substrate that is provided as a target for substrate processing is provided in an inside thereof and an exhaust port that discharges a gas in an inside thereof is formed at a position that is lower than that of the stage around the stage; a baffle plate that is provided around the stage and divides an inside of the chamber into a processing space where substrate processing is executed for the substrate and an exhaust space that includes the exhaust port; an ejection port that is arranged to eject a gas to the exhaust space; and a gas supply unit that supplies a cleaning gas that reacts with a product that is produced in the exhaust space to the ejection port.

### BRIEF DESCRIPTION OF DRAWINGS

FIG. 1 is a diagram that illustrates an example of schematic configuration of a plasma processing apparatus according to an embodiment.

FIG. 2 is a diagram that illustrates an example of arrangement of gas ejection ports according to an embodiment.

FIG. 3 is a diagram that illustrates an example of a flow of a cleaning gas according to an embodiment.

FIG. 4 is a diagram that illustrates another example of arrangement of gas ejection ports according to an embodiment.

FIG. 5A is a diagram that illustrates another example of arrangement of gas ejection ports according to an embodiment.

FIG. 5B is a diagram that illustrates another example of arrangement of gas ejection ports according to an embodiment.

### DESCRIPTION OF EMBODIMENTS

Hereinafter, embodiments of a substrate processing apparatus and a cleaning method as disclosed in the present application will be explained in detail with reference to the drawings. Additionally, a substrate processing apparatus and a cleaning method as disclosed therein are not limited by the present embodiments.

A substrate processing apparatus has been known that depressurizes an inside of a chamber thereof and executes substrate processing such as plasma processing for a substrate. A substrate processing apparatus is frequently provided in such a manner that a stage that places a substrate thereon is provided at a center of a chamber and an exhaust port is formed near an end of a bottom surface of the chamber, in view of a space limitation and/or a maintenance characteristic. In such a substrate processing apparatus, in a case where a gas is discharged from an exhaust port so as to depressurize an inside of a chamber, a deviation of an exhaust characteristic is caused. Hence, in a plasma processing apparatus, a baffle plate is provided around a stage so as to homogenize an exhaust characteristic.

Meanwhile, in a substrate processing apparatus, a deposition substance is deposited in a chamber. For example, in a plasma processing apparatus, a deposition substance is deposited in a processing space where substrate processing is executed in a chamber, where such a deposition substance is also readily deposited in an exhaust space that is provided on a side of an exhaust port relative to a baffle plate in the chamber. For a technique that removes such a deposition substance, in Patent Literature 1, a film is formed on a surface of a component and such a film is removed so as to execute cleaning. However, formation of a film and removal of the film have to be executed for cleaning, and further, it is impossible to remove a deposition substance in an exhaust space efficiently.

Hence, a technique that removes a deposition substance in an exhaust space efficiently is expected.

### EMBODIMENTS

Apparatus Configuration

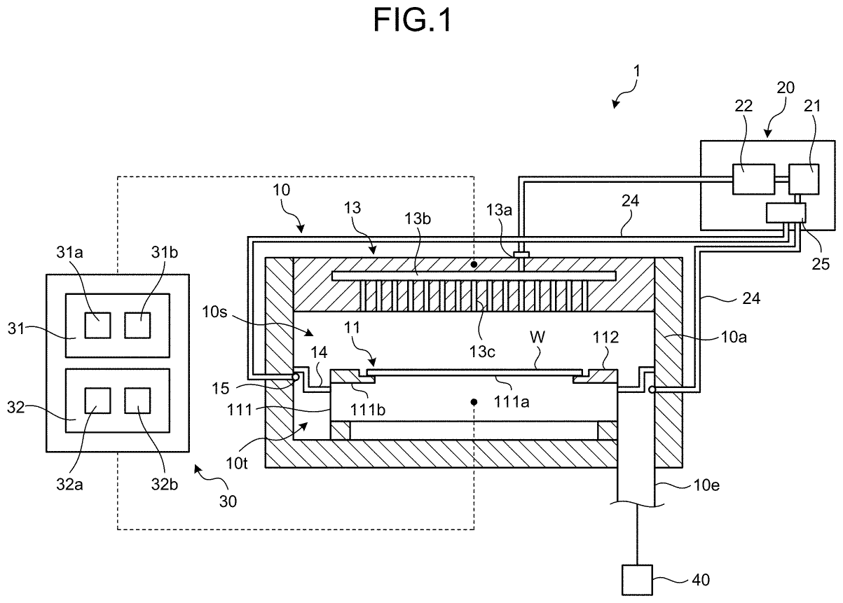

An example of a substrate processing apparatus in the present disclosure will be explained. In an embodiment, a case where a substrate processing apparatus in the present disclosure is provided as a plasma processing apparatus that executes plasma processing such as plasma etching will be explained as an example. FIG. 1 is a diagram that illustrates an example of a schematic configuration of a plasma processing apparatus 1 according to an embodiment.

A configuration example of a capacitively coupled plasma processing apparatus as an example of the plasma processing apparatus 1 will be explained below. A capacitively coupled plasma processing apparatus 1 includes a plasma processing chamber 10, a gas supply unit 20, a power source 30, and an exhaust system 40. Furthermore, the plasma processing apparatus 1 includes a substrate supporting unit 11 and a gas introduction unit. The gas introduction unit is configured to introduce at least one processing gas into the plasma processing chamber 10. The gas introduction unit includes a shower head 13. The substrate supporting unit 11 is arranged inside the plasma processing chamber 10. The shower head 13 is arranged above the substrate supporting unit 11. In an embodiment, the shower head 13 composes at least a part of a top part (ceiling) of the plasma processing chamber 10. The plasma processing chamber 10 has a plasma processing space 10s that is defined by the shower head 13, a side wall 10a of the plasma processing chamber 10, and the substrate supporting unit 11. The side wall 10a is grounded. The shower head 13 and the substrate supporting unit 11 are electrically insulated from a housing of the plasma processing chamber 10.

The substrate supporting unit 11 includes a body unit 111 and a ring assembly 112. The body unit 111 has a central area (substrate supporting surface) 111a for supporting a substrate (wafer) W and a ring area (ring supporting surface) 111b for supporting the ring assembly 112. The ring area 111b of the body unit 111 surrounds the central area 111a of the body unit 111 in a plan view. A substrate W is arranged on the central area 111a of the body unit 111 and the ring assembly 112 is arranged on the ring area 111b of the body unit 111 so as to surround such a substrate W on the central area 111a of the body unit 111. In an embodiment, the body unit 111 includes a base and an electrostatic chuck. The base includes a conductive member. The conductive member of the base functions as a lower electrode. The electrostatic chuck is arranged on the base. An upper surface of the electrostatic chuck has the substrate supporting surface 111a. The ring assembly 112 includes one or more ring members. At least one of the one or more ring members is an edge ring. Furthermore, the substrate supporting unit 11 may include a temperature regulation module that is configured to regulate at least one of the electrostatic chuck, the ring assembly 112, and a substrate at a target temperature, although illustration thereof is omitted. The temperature regulation module may include a heater, a heat transfer medium, a flow channel, or a combination thereof. A heat transfer fluid such as brine and/or a gas flows through the flow channel. Furthermore, the substrate supporting unit 11 may include a heat transfer gas supply unit that is configured to supply a heat transfer gas between a back surface of a substrate W and the substrate supporting surface 111a.

The shower head 13 is configured to introduce at least one processing gas from the gas supply unit 20 into the plasma processing space 10s. The shower head 13 has at least one gas supply port 13a, at least one gas diffusion room 13b, and a plurality of gas introduction ports 13c. A processing gas that is supplied to a gas supply port 13a passes through a gas diffusion room 13b and is introduced from the plurality of gas introduction ports 13c into the plasma processing space 10s. Furthermore, the shower head 13 includes a conductive member. The conductive member of the shower head 13 functions as an upper electrode. Additionally, the gas introduction unit may include one or more side gas injection units (SGI: Side Gas Injector) that are attached to one or more openings that are formed on the side wall 10a, in addition to the shower head 13.

The gas supply unit 20 may include at least one gas source 21 and at least one flow volume controller 22. In an embodiment, the gas supply unit 20 is configured to supply at least one processing gas from a gas source 21 that corresponds thereto to the shower head 13 through a flow volume controller 22 that corresponds thereto. Each flow volume controller 22 may include, for example, a mass flow controller or a pressure control type flow volume controller. Moreover, the gas supply unit 20 may include at least one flow volume modulation device that modulates, or provides pulses of, a flow volume of at least one processing gas.

The power source 30 includes an RF power source 31 that is coupled to the plasma processing chamber 10 through at least one impedance matching circuit. The RF power source 31 is configured to supply at least one RF signal (RF power) such as a source RF signal and a bias RF signal to the conductive member of the substrate supporting unit 11 and/or the conductive member of the shower head 13. Thereby, plasma is formed from at least one processing gas that is supplied to the plasma processing space 10s. Therefore, it is possible for the RF power source 31 to function as at least a part of a plasma production unit 12. Furthermore, a bias potential is generated at a substrate W by supplying a bias RF signal to the conductive member of the substrate supporting unit 11, so that it is possible to attract an ionic component in formed plasma to such a substrate W.

In an embodiment, the RF power source 31 includes a first RF production unit 31a and a second RF production unit 31b. The first RF production unit 31a is configured to be coupled to the conductive member of the substrate supporting unit 11 and/or the conductive member of the shower head 13 through the at least one impedance matching circuit and produce a source RF signal (source RF power) for plasma production. In an embodiment, a source RF signal has a frequency within a range of 13 MHz to 150 MHz. In an embodiment, the first RF production unit 31a may be configured to produce a plurality of source RF signals that have different frequencies. One or more produced source RF signals are supplied to the conductive member of the substrate supporting unit 11 and/or the conductive member of the shower head 13. The second RF production unit 31b is configured to be coupled to the conductive member of the substrate supporting unit 11 through the at least one impedance matching circuit and produce a bias RF signal (bias RF power). In an embodiment, a bias RF signal has a frequency that is lower than that of a source RF signal. In an embodiment, a bias RF signal has a frequency within a range of 400 kHz to 13.56 MHz. In an embodiment, the second RF production unit 31b may be configured to produce a plurality of bias RF signals that have different frequencies. One or more produced bias RF signals are supplied to the conductive member of the substrate supporting unit 11. Furthermore, in a variety of embodiments, pulses of at least one of a source RF signal and a bias RF signal may be provided.

Furthermore, the power source 30 may include a DC power source 32 that is coupled to the plasma processing chamber 10. The DC power source 32 includes a first DC production unit 32a and a second DC production unit 32b. In an embodiment, the first DC production unit 32a is configured to be connected to the conductive member of the substrate supporting unit 11 and produce a first DC signal. A produced first DC signal is applied to the conductive member of the substrate supporting unit 11. In an embodiment, a first DC signal may be applied to another electrode such as an electrode in the electrostatic chuck. In an embodiment, the second DC production unit 32b is configured to be connected to the conductive member of the shower head 13 and produce a second DC signal. A produced second DC signal is applied to the conductive member of the shower head 13. In a variety of embodiments, pulses of first and second DC signals may be provided. Additionally, the first and second DC production units 32a, 32b may be provided in addition to the RF power source 31 or the first DC production unit 32a may be provided instead of the second RF production unit 31b.

The plasma processing chamber 10 is formed into a hollow cylindrical shape where a space is formed in an inside thereof and the substrate supporting unit 11 as described above is arranged at a center of an inside thereof. A substrate W that is formed into a solid cylindrical shape and provided as a target for substrate processing is placed on the substrate supporting unit 11. Furthermore, a gas discharge port 10e that discharges a gas in an inside thereof is formed on the plasma processing chamber 10 at a position that is lower than that of the substrate supporting unit 11 around the substrate supporting unit 11. In the plasma processing apparatus 1 according to an embodiment, the gas discharge port 10e is formed on a bottom part of the plasma processing chamber 10.

It is possible to provide, for example, the exhaust system 40 that is connected to the gas discharge port 10e that is provided on a bottom part of the plasma processing chamber 10. The exhaust system 40 may include a pressure regulation valve and a vacuum pump. A pressure in the plasma processing space 10s is regulated by the pressure regulation valve. The vacuum pump may include a turbo-molecular pump, a dry pump, or a combination thereof.

In the plasma processing chamber 10, a baffle plate 14 is provided around the substrate supporting unit 11. The baffle plate 14 is provided with a flat ring shape. In the baffle plate 14 according to an embodiment, flat planar surfaces are formed on an inner peripheral side and an outer peripheral side thereof and a step is formed in such a manner that the outer peripheral side is higher than the inner peripheral side. Additionally, the baffle plate 14 may be formed of a planar surface with no step. The baffle plate 14 is arranged so as to surround a periphery of the substrate supporting unit 11. In the baffle plate 14, the inner peripheral side is fixed on the substrate supporting unit 11 and the outer peripheral side is fixed on an inner side wall of the plasma processing chamber 10. Multiple slits and/or holes are formed on the baffle plate 14, so that a gas is capable of passing therethrough. The baffle plate 14 divides an inside of the plasma processing chamber 10 into the plasma processing space 10s that is a processing space where substrate processing is executed for a substrate W and an exhaust space 10t that includes the gas discharge port 10e. The plasma processing space 10s is a space on an upstream side of the baffle plate 14 relative to a flow of an exhaust gas to the gas discharge port 10e. The exhaust space 10t is a space on a downstream side of the baffle plate 14 relative to a flow of an exhaust gas to the gas discharge port 10e.

In the plasma processing chamber 10, a gas ejection port 15 is provided in the exhaust space 10t. In an embodiment, the gas ejection port 15 is provided on an upstream side of the exhaust space 10t relative to a flow of an exhaust gas to the gas discharge port 10e. For example, the gas ejection port 15 is provided on an inner side wall of the plasma processing chamber 10 below the baffle plate 14. A plurality of gas ejection ports 15 are provided on an inner side wall of the plasma processing chamber 10 so as to be oriented in a peripheral direction thereof.

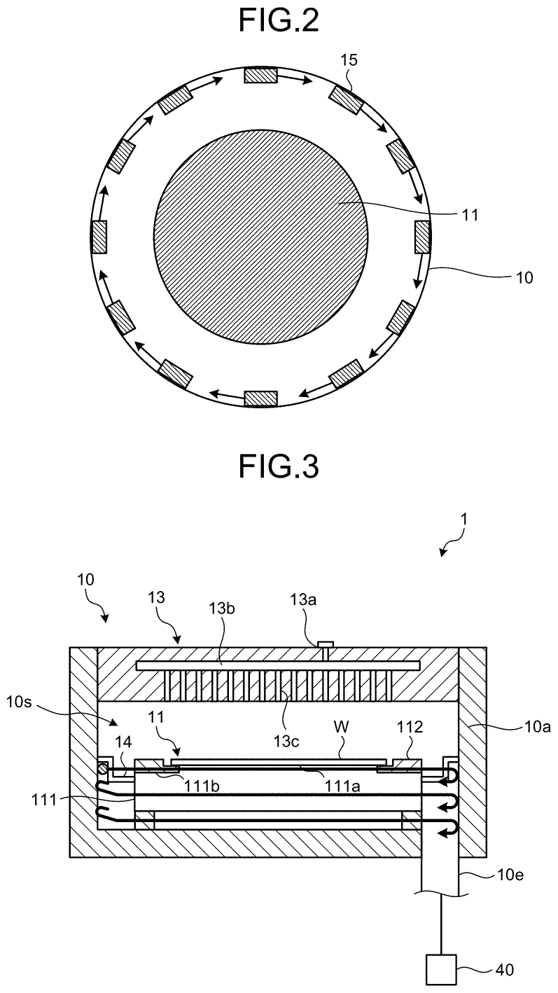

FIG. 2 is a diagram that illustrates an example of arrangement of gas ejection ports 15 according to an embodiment. FIG. 2 is a top view of an inside of a plasma processing chamber 10. A substrate supporting unit 11 with a circular shape is arranged at a center of an inside of the plasma processing chamber 10. A plurality of gas ejection ports 15 are provided on an inner side wall of the plasma processing chamber 10 at a predetermined intervals so as to be oriented in a peripheral direction thereof. Additionally, each gas ejection port 15 is oriented in a certain direction. Furthermore, as an orientation thereof in a certain direction is attained, such a direction is not limiting where a clockwise direction may be provided as illustrated in FIG. 2 or a counterclockwise direction may be provided in an opposite manner.

FIG. 1 is returned to. Each gas ejection port 15 is connected to the gas supply unit 20. The gas supply unit 20 supplies a gas to each gas ejection port 15. For example, the gas supply unit 20 supplies a cleaning gas for cleaning to each gas ejection port 15. The gas supply unit 20 is provided so as to be capable of controlling a flow volume of a gas that is supplied to each gas ejection port 15. In an embodiment, the gas supply unit 20 is connected to respective gas ejection ports 15 separately by respective pipes 24. Flow volume controllers 25 are respectively provided on the respective pipes 24. The gas supply unit 20 is configured to supply a cleaning gas from respective corresponding gas sources 21 to the respective gas ejection ports 15 through respective corresponding flow volume controllers 25. The gas supply unit 20 controls a flow volume of a gas by the flow volume controllers 25, so that it is possible to control a flow volume of a gas that is supplied to each gas ejection port 15. Additionally, a structure may be provided in such a manner that a flow volume of a gas is controlled by one flow volume controller 25 and the gas is distributed to the respective pipes 24 separately. Furthermore, a structure may be provided in such a manner that a gas is delivered from one flow volume controller 25 through one pipe 24 and the gas is distributed just in front of the respective gas ejection ports 15.

Meanwhile, in the plasma processing apparatus 1, although a deposition substance is deposited in the plasma processing space 10s where substrate processing is executed in the plasma processing chamber 10 as described above, a deposition substance is also readily deposited in the exhaust space 10t that is provided on a side of the gas discharge port 10e of the baffle plate 14 in the plasma processing chamber 10. Such a deposition substance includes a product that is produced by plasma processing, ash that is provided by heat, or the like.

Hence, a deposition substance in the exhaust space 10t is removed by a cleaning process in a cleaning method according to an embodiment. The plasma processing apparatus 1 according to an embodiment executes a cleaning process that removes a deposition substance in the exhaust space 10t. A timing when a cleaning process is executed may be any timing during substrate processing. For example, the plasma processing apparatus 1 may execute a cleaning process simultaneously with plasma processing such as plasma etching. Furthermore, the plasma processing apparatus 1 may execute substrate processing for a certain number of a substrates W and subsequently execute a process that recovers a state of an inside of the plasma processing chamber 10 by dry cleaning or the like. For example, the plasma processing apparatus 1 executes dry cleaning that cleans the plasma processing space 10s on an upstream side of the baffle plate 14. The plasma processing apparatus 1 may execute a cleaning process in a cleaning method according to an embodiment during dry cleaning for the plasma processing space 10s or subsequent to such dry cleaning. Furthermore, the plasma processing apparatus 1 may alternately execute dry cleaning for the plasma processing space 10s and a cleaning process in a cleaning method according to an embodiment multiple times.

Dry cleaning may be executed by placing a dummy substrate on the substrate supporting unit 11 in order to protect a surface of the substrate supporting unit 11. Even in a cleaning process in a cleaning method according to an embodiment, particles that flows back above the baffle plate 14 are present more than slightly, so that it is desirable to place a dummy substrate on the substrate supporting unit 11 and execute it.

In a case where a cleaning process in a cleaning method according to an embodiment is executed, the plasma processing apparatus 1 controls the gas supply unit 20 so as to supply a cleaning gas from the gas supply unit 20 to the plurality of gas ejection ports 15 and eject such a cleaning gas from the gas ejection ports 15.

A cleaning gas may be provided as plasma and ejected from a gas ejection port 15. For example, a plasma generation unit such as a plasma source that provides a gas as plasma may be provided on a pipe 24 so as to provide a cleaning gas as plasma and eject an active species of a cleaning gas provided as plasma from a gas ejection port 15. A cleaning gas may be provided as plasma in the plasma processing chamber 10. For example, a parallel plate type electrode for plasma generation and/or an antenna coil for inductively-coupled-type plasma may be installed below the baffle plate 14 so as to provide a cleaning gas that is ejected from a gas ejection port 15 as plasma in the plasma processing chamber 10.

A cleaning gas may be any gas species that is capable of removing a deposition substance. For example, in a case where a deposition substance is an organic product that is produced from an etching gas at a time of an etching process for a substrate W, it is possible to provide an oxygen-containing gas such as O₂, O₃, CO, or CO₂ as a cleaning gas. An O₃ gas) is a gas with a high reactivity even if plasma is not used. Furthermore, in a case where a deposition substance is an organic film that includes a metal such as W (tungsten) or Ti (titanium), it is possible to provide an oxygen-containing gas such as O₂, CO, O₃, or CO₂, a gas where a halogen-containing gas such as CF₄ or Cl₂ is added to an oxygen-containing gas, an F₂ gas, and/or a ClF₂ gas as a cleaning gas. An F₂ gas or a ClF₂ gas is a gas with a high reactivity even if plasma is not used. Furthermore, a deposition substance is a deposition substance in metal etching such as Ru (ruthenium), cobalt (Co), or iron (Fe), it is possible to provide a methanol (CH₃OH) gas as a cleaning gas. Furthermore, multiple types of gasses may be switched and supplied as cleaning gasses. In a case where a deposition substance is a laminated film of a plurality of products and/or organic films, it is sufficient to select a gas species depending on a type of a film that is exposed to an outermost surface of a laminated film and supply it as a cleaning gas. In a case where a cleaning process is executed simultaneously with a plasma process where a plurality of step processes where reaction products that are provided as deposition substances are different are executed, cleaning gasses may be switched for each step process.

Each gas ejection port 15 is provided on an inner side wall of the plasma processing chamber 10 so as to be oriented in a peripheral direction thereof. Each gas ejection port 15 ejects a cleaning gas toward a peripheral direction of the plasma processing chamber 10. FIG. 3 is a diagram that illustrates an example of a flow of a cleaning gas according to an embodiment. A cleaning gas that is ejected from each gas ejection port 15 swirls along an inner wall of a plasma processing chamber 10 in a peripheral direction thereof. Thus, a cleaning gas swirls along an inner wall of the plasma processing chamber 10 so as to increase a period of time when such a cleaning gas contacts the inner wall of the plasma processing chamber 10, so that it is possible to remove a deposition substance in an exhaust space efficiently. Furthermore, a cleaning gas is ejected from each gas ejection port 15, so that it is possible to generate a swirling flow that is a fast flow along an inner wall of the plasma processing chamber 10 and it is possible to remove a deposition substance that is attached to the inner wall of the plasma processing chamber 10 by such a swirling flow efficiently.

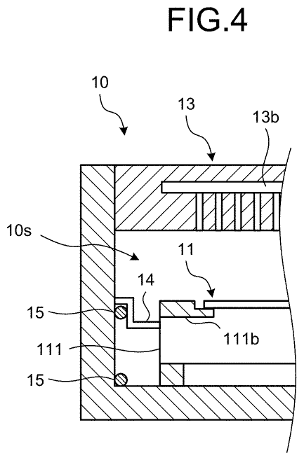

Additionally, although a case where the gas ejection port 15 is provided on an inner side wall of the plasma processing chamber 10 below the baffle plate 14 has been explained as an example in an embodiment as described above, this is not limiting. The gas ejection port 15 may be provided anywhere in the exhaust space 10t. For example, the gas ejection port 15 may be provided on each of an upstream side and a downstream side of the exhaust space 10t relative to a flow of an exhaust gas to the gas discharge port 10e. FIG. 4 is a diagram that illustrates another example of arrangement of gas ejection ports 15 according to an embodiment. FIG. 4 is a side view of an inside of a plasma processing chamber 10. In FIG. 4, a gas ejection port 15 is provided on each of an inner side wall of the plasma processing chamber 10 below a baffle plate 14 and a peripheral part of a bottom surface of the plasma processing chamber 10. Each gas ejection port 15 is arranged so as to be oriented in a peripheral direction of the plasma processing chamber 10. Thereby, it is possible to generate a swirling flow of a cleaning gas along an inner wall of the plasma processing chamber 10 on each of an upstream side and a downstream side of an exhaust space 10t, so that it is possible to remove a deposition substance that is attached to the inner wall of the plasma processing chamber 10 by such a swirling flow efficiently. Furthermore, a cleaning gas may be ejected simultaneously from each of an upstream side and a downstream side of the exhaust space 10t, a cleaning gas may be ejected from at least one of the upstream side and the downstream side and subsequently be switched to another side, or ejection thereof may be executed alternately therebetween. Furthermore, the gas ejection port 15 may be arranged on one of an upstream side and a downstream side of the exhaust space 10t relative to a flow of an exhaust gas to a gas discharge port 10e.

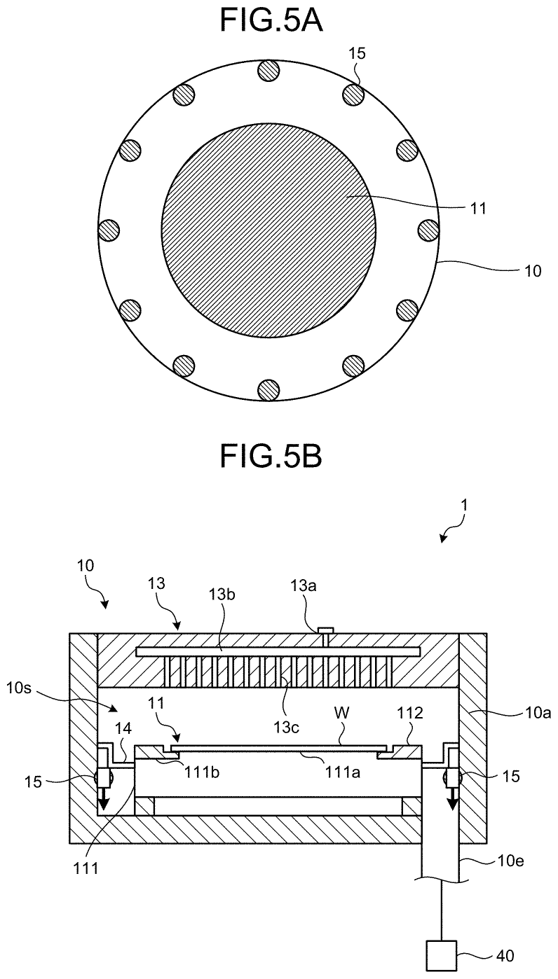

Furthermore, although a case where each gas ejection port 15 is arranged so as to be oriented in a peripheral direction of the plasma processing chamber 10 so as to cause a cleaning gas to swirl along an inner wall of the plasma processing chamber 10 in the peripheral direction thereof has been explained as an example in an embodiment as described above, this is not limiting. Each gas ejection port 15 may be arranged so as to be oriented toward a downstream side relative to a flow of an exhaust gas to the gas discharge port 10e along an inner side wall of the plasma processing chamber 10. FIG. 5A and FIG. 5B are diagrams that illustrate another example of arrangement of gas ejection ports 15 according to an embodiment. FIG. 5A is a side view of an inside of a plasma processing chamber 10. FIG. 5B is a top view of an inside of the plasma processing chamber 10. In FIG. 5A and FIG. 5B, a gas ejection port 15 is provided on an inner side wall of the plasma processing chamber 10 below a baffle plate 14. Each gas ejection port 15 is arranged along a peripheral direction of the plasma processing chamber 10. A cleaning gas that is ejected from each gas ejection port 15 flows in a downward direction along an inner wall of the plasma processing chamber 10, so that a curtain-like downward flow of such a cleaning gas is generated on the inner wall of the plasma processing chamber 10. Whereas, in general, in a case where a gas flows in a space, a speed of a gas around an inner wall in the space is less than a speed of a gas that flows at a central part of the space, a cleaning gas is ejected along an inner wall of the plasma processing chamber 10 in a practical example as described above, so that it is possible to generate a flow of a gas that is fast even around the inner wall of the plasma processing chamber 10. Thereby, it is possible to remove a deposition substance that is attached to an inner wall of the plasma processing chamber 10 efficiently. A curtain-like cleaning gas flows on an inner wall of the plasma processing chamber 10, so that it is possible to prevent a deposition substance from being readily attached to the inner wall of the plasma processing chamber 10. Additionally, although each gas ejection port 15 is arranged so as to be oriented toward a downstream side, it does not have to be perpendicular to the gas discharge port 10e or may be arranged so as to be oriented obliquely relative to the downstream side. Thereby, it is also possible to generate a swirling flow.

As provided above, a plasma processing apparatus 1 according to an embodiment has a plasma processing chamber 10 (a chamber), a baffle plate 14, a gas ejection port 15 (an ejection port), and a gas supply unit 20. In the plasma processing chamber 10, a substrate supporting unit 11 (a stage) that places a substrate W that is provided as a target for substrate processing is provided in an inside thereof and a gas discharge port 10e (an exhaust port) that discharges a gas in an inside thereof is formed at a position that is lower than that of the substrate supporting unit 11 around the substrate supporting unit 11. The baffle plate 14 is provided around the substrate supporting unit 11 and divides an inside of the plasma processing chamber 10 into a plasma processing space 10s (a processing space) where substrate processing is executed for the substrate W and an exhaust space 10t that includes the gas discharge port 10e. The gas ejection port 15 is arranged so as to eject a gas to the exhaust space 10t. The gas supply unit 20 supplies a cleaning gas that reacts with a product that is produced in the exhaust space 10t to the gas ejection port 15. Thereby, it is possible for the plasma processing apparatus 1 to remove a deposition substance in the exhaust space 10t efficiently.

Furthermore, the gas ejection port 15 is arranged on at least one of an upstream side and a downstream side of the exhaust space 10t relative to a flow of an exhaust gas to the gas discharge port 10e. Thereby, it is possible for the plasma processing apparatus 1 to remove a deposition substance on each of an upstream side and a downstream side of the exhaust space 10t efficiently.

Furthermore, the gas ejection port 15 is provided on an inner side wall of the plasma processing chamber 10 below the baffle plate 14. Thereby, it is possible for the plasma processing apparatus 1 to clean a lower part of the baffle plate 14 where a deposition substance is readily deposited efficiently.

Furthermore, a plurality of the gas ejection port 15 are arranged so as to surround a periphery of the substrate supporting unit 11 on an inner side wall of the plasma processing chamber 10 and respectively eject a cleaning gas toward a peripheral direction thereof. Thereby, it is possible for the plasma processing apparatus 1 to generate a swirling flow that is a fast flow along an inner wall of the plasma processing chamber 10, so that it is possible to remove a deposition substance that is attached to the inner wall of the plasma processing chamber 10 by such a swirling flow efficiently.

Furthermore, a plurality of the gas ejection port 15 are arranged so as to surround a periphery of the substrate supporting unit 11 on an inner side wall of the plasma processing chamber 10 and respectively eject a cleaning gas toward a downward direction. Thereby, it is possible for the plasma processing apparatus 1 to generate a curtain-like flow of a cleaning gas on an inner wall of the plasma processing chamber 10, so that it is possible to remove a deposition substance that is attached to the inner wall of the plasma processing chamber 10 efficiently.

Furthermore, the gas supply unit 20 supplies a cleaning gas during dry cleaning in the plasma processing chamber 10 or subsequent to the dry cleaning so as to eject a cleaning gas from the gas ejection port 15. Thereby, it is possible for the plasma processing apparatus 1 to remove a deposition substance that is attached to an inner wall of the plasma processing chamber 10 at a timing of dry cleaning.

Although embodiments have been explained above, it should be considered that embodiments as disclosed herein are not limitative but are illustrative in all aspects. In fact, it is possible to implement embodiments as described above in a variety of forms thereof. Furthermore, embodiments as described above may be omitted, substituted, or modified in a variety of forms thereof, without departing from what is claimed and an essence thereof.

For example, although a case where plasma processing is executed for a semiconductor wafer as a substrate W has been explained as an example in an embodiment as described above, this is not limiting. Any substrate W may be provided.

Furthermore, although a case where a substrate processing apparatus is provided as the plasma processing apparatus 1 that executes plasma processing has been explained as an example in an embodiment as described above, this is not limiting. A substrate processing apparatus may be any apparatus that executes substrate processing for a substrate W. For example, a substrate processing apparatus may be a film formation apparatus or the like.

According to the present disclosure, it is possible to remove a deposition substance in an exhaust space efficiently.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising:
a chamber where a stage that places a substrate that is provided as a target for substrate processing is provided in an inside thereof and an exhaust port that discharges a gas in an inside thereof is formed at a position that is lower than that of the stage around the stage;
a baffle plate that is provided around the stage and divides an inside of the chamber into a processing space where substrate processing is executed for the substrate and an exhaust space that includes the exhaust port;
an ejection port that is arranged to eject a gas to the exhaust space; and
a gas supply unit that supplies a cleaning gas that reacts with a product that is produced in the exhaust space to the ejection port.

2. The substrate processing apparatus according to claim 1, wherein
the ejection port is arranged on at least one of an upstream side and a downstream side of the exhaust space relative to a flow of an exhaust gas to the exhaust port.

3. The substrate processing apparatus according to claim 1, wherein
the ejection port is provided on an inner side wall of the chamber below the baffle plate.

4. The substrate processing apparatus according to claim 1, wherein
a plurality of the ejection ports are arranged to surround a periphery of the stage on an inner side wall of the chamber and respectively eject a cleaning gas toward a peripheral direction thereof.

5. The substrate processing apparatus according to claim 1, wherein
a plurality of the ejection ports are arranged to surround a periphery of the stage on an inner side wall of the chamber and respectively eject a cleaning gas toward a downward direction.

6. The substrate processing apparatus according to claim 1, wherein
the gas supply unit supplies a cleaning gas during dry cleaning in the chamber or subsequent to the dry cleaning to eject a cleaning gas from the ejection port.

7. A cleaning method for a substrate processing apparatus including a chamber where a stage that places a substrate that is provided as a target for substrate processing is provided in an inside thereof and an exhaust port that discharges a gas in an inside thereof is formed at a position that is lower than that of the stage around the stage, a baffle plate that is provided around the stage and divides an inside of the chamber into a processing space where substrate processing is executed for the substrate and an exhaust space that includes the exhaust port, an ejection port that is arranged to eject a gas to the exhaust space, and a gas supply unit that is capable of supplying a cleaning gas that reacts with a product that is produced in the exhaust space to the ejection port, wherein,
in cleaning, a cleaning gas is supplied from the gas supply unit to eject a cleaning gas from the ejection port.
